(19) United States
(12) Patent Application Publication
(10) Pub. No.: US 2024/0251547 A1
(43) Pub. Date: Jul. 25, 2024

(54) SEMICONDUCTOR DEVICE INCLUDING A BURIED CELL ARRAY TRANSISTOR (BCAT) STRUCTURE AND MANUFACTURING METHOD THEREOF

(71) Applicant: SAMSUNG ELECTRONICS CO., LTD., SUWON-SI (KR)

(72) Inventors: Byeongjun BAE, Suwon-si (KR); Jungwoo SONG, Suwon-si (KR)

(21) Appl. No.: 18/406,265

(22) Filed: Jan. 8, 2024

(30) Foreign Application Priority Data
Jan. 20, 2023 (KR) 10-2023-0009035

(51) Int. Cl. H10B 12/00

(52) U.S. Cl. CPC H10B 12/34; H10B 12/053; H10B 12/315; H10B 12/482; H10B 12/488

(57) ABSTRACT

A semiconductor device includes: an active area formed on a substrate; bit lines extending in a first direction and formed inside the substrate by passing through the active area, wherein the bit lines are formed at first intervals in a second direction that is substantially perpendicular to the first direction; word lines formed inside the substrate by passing through the active area, and extending below the bit lines in the second direction, wherein the word lines are formed at second intervals in the first direction; a contact structure formed on the active area and adjacent to the bit lines, wherein the contact structure includes a metal layer and an adhesive layer; and a capacitor structure formed on the contact structure, wherein the active area is inclined in a third direction having a certain slope with respect to the first direction.

### CROSS-REFERENCE TO RELATED APPLICATION

This application claims priority under 35 U.S.C. § 119 to Korean Patent Application No. 10-2023-0009035, filed on Jan. 20, 2023, in the Korean Intellectual Property Office, the disclosure of which is incorporated by reference herein in its entirety.

### TECHNICAL FIELD

Embodiments of the present inventive concept relate to a semiconductor device and a manufacturing method thereof. More particularly, embodiments of the present inventive concept relate to a semiconductor device including a buried cell array transistor (BCAT) structure and a manufacturing method thereof.

### DISCUSSION OF THE RELATED ART

Along with the rapid development of the electronics industry and the demands of users, electronic devices have been gradually made smaller and lighter in weight. As a result, semiconductor devices have become increasingly integrated. Therefore, because semiconductor devices, with a high degree of integration, are in demand for electronic devices, the design rules for components of a semiconductor device have decreased. Accordingly, the difficulty of a manufacturing process of ensuring connection reliability between conductive patterns constituting a semiconductor device has gradually increased.

Along with a gradual increase in the integration of a semiconductor device, a structure of a semiconductor device in which a plurality of word lines have a BCAT in a substrate has been under development.

### SUMMARY

According to an embodiment of the present inventive concept, a semiconductor device includes: an active area formed on a substrate; bit lines extending in a first direction and formed inside the substrate by passing through the active area, wherein the bit lines are formed at first intervals in a second direction that is substantially perpendicular to the first direction; word lines formed inside the substrate by passing through the active area, and extending below the bit lines in the second direction, wherein the word lines are formed at second intervals in the first direction; a contact structure formed on the active area and adjacent to the bit lines, wherein the contact structure includes a metal layer and an adhesive layer; and a capacitor structure formed on the contact structure, wherein the active area is inclined in a third direction having a certain slope with respect to the first direction.

According to an embodiment of the present inventive concept, a method of manufacturing a semiconductor device includes: defining an active area by forming a device isolation layer on a substrate; forming a word line extending in a second direction across the active area and the device isolation layer; forming a first capping layer covering the word line; forming a bit line extending in a first direction across the first capping layer, the active area, and the device isolation layer, wherein the first direction is substantially perpendicular to the second direction; forming a second capping layer covering the bit line; forming a contact structure including a metal layer and an adhesive layer on the second capping layer; forming a third capping layer on the contact structure; and forming a capacitor structure on the third capping layer, wherein the defining of the active area includes defining that the active area is inclined in a third direction having a certain slope with respect to the first direction, wherein the third direction is inclined by about 30° with respect to the first direction.

According to an embodiment of the present inventive concept, a semiconductor device includes: an active area formed on a substrate; bit lines extending in a first direction and formed inside the substrate by passing through the active area, and wherein the bit lines are formed at first intervals in a second direction that is substantially perpendicular to the first direction; word lines formed inside the substrate by passing through the active area, and extending below the bit lines in the second direction, wherein the word lines are formed at second intervals in the first direction; a first capping layer disposed on the word lines; a second capping layer disposed on the bit lines; a contact structure formed on the active area and adjacent to the bit lines, wherein the contact structure includes a metal layer and an adhesive layer; a third capping layer disposed on the contact structure; and a capacitor structure formed in a honeycomb structure on the contact structure, wherein the active area is inclined by about 30° with respect to the first direction by being arranged at a ratio of two first intervals to four second intervals.

### BRIEF DESCRIPTION OF THE DRAWINGS

The above and other aspects of the present inventive concept will become more apparent by describing in detail embodiments thereof, with reference to the accompanying drawings, in which:

FIG. 1 is a layout diagram schematically illustrating a semiconductor device according to an embodiment of the present inventive concept;

FIG. 2 is a magnified layout diagram illustrating a portion of a cell array area of FIG. 1;

FIG. 3 illustrates cross-sectional views taken along lines A-A′ and B-B′ of FIG. 2;

FIG. 4 is a cross-sectional view of a core area of a semiconductor device in a first direction, according to an embodiment of the present inventive concept;

FIGS. 5, 6, 7, 8, 9, 10, 11, and 12 illustrate a method of manufacturing a semiconductor device with cross-sectional views taken along lines A-A′ and B-B′, according to an embodiment of the present inventive concept; and

FIG. 13 is a graph illustrating the number of processes for each operation in a method of manufacturing a semiconductor device, according to an embodiment of the present inventive concept.

### DETAILED DESCRIPTION OF THE EMBODIMENTS

Hereinafter, embodiments of the present inventive concept are described in detail with reference to the accompanying drawings. Like reference numerals in the drawings and specification denote like elements, and thus their repetitive description is omitted or briefly discussed.

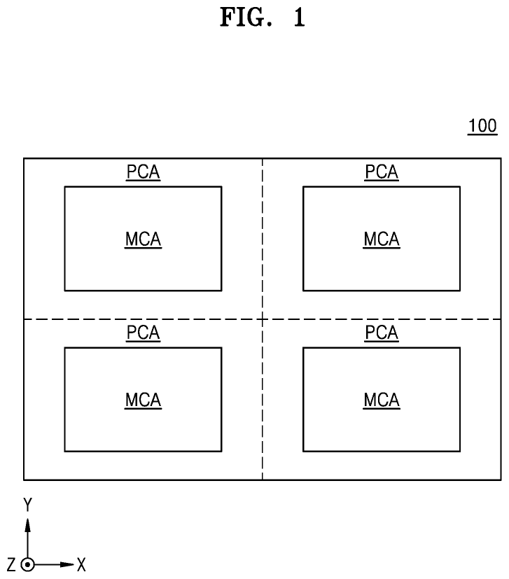

FIG. 1 is a layout diagram schematically illustrating a semiconductor device 100 according to an embodiment of the present inventive concept.

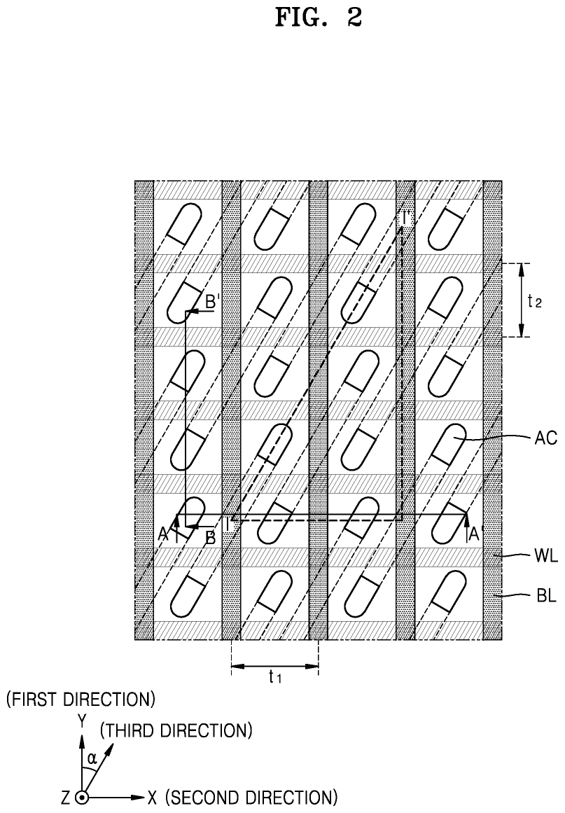

FIG. 2 is a magnified layout diagram illustrating a portion of a cell array area MCA of FIG. 1.

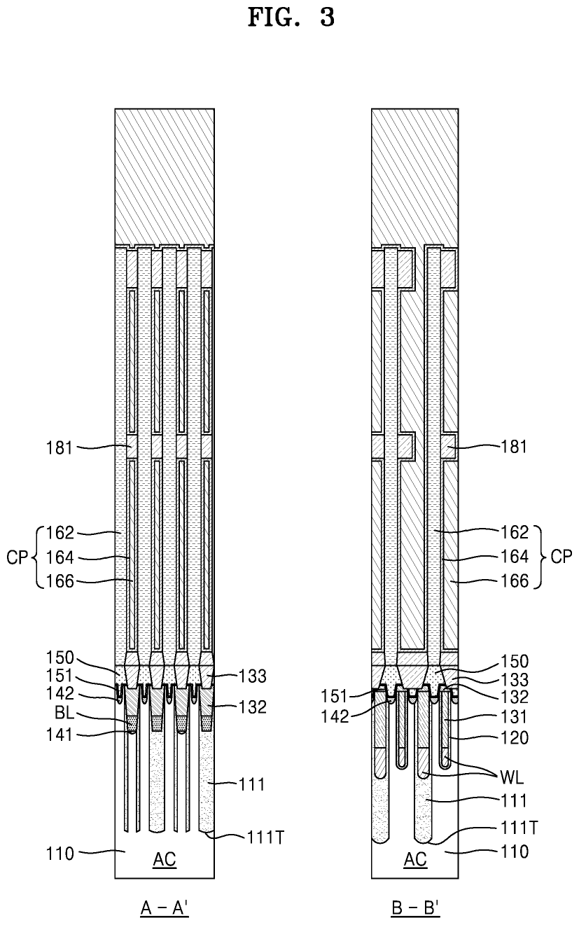

Referring to FIGS. 1 and 2, the semiconductor device 100 may include a substrate 110 (see FIG. 3) including the cell array area MCA and a peripheral circuit area PCA. According to some embodiments of the present inventive concept, the substrate 110 may include an interface area between the cell array area MCA and the peripheral circuit area PCA.

According to some embodiments of the present inventive concept, the cell array area MCA may be a memory cell array of a dynamic random access memory (DRAM) device, and the peripheral circuit area PCA may be a core area or a peripheral circuit area of the DRAM device. For example, the cell array area MCA may include a cell transistor and a capacitor structure that is connected to the cell transistor, and the peripheral circuit area PCA may include a peripheral circuit transistor that is configured to provide a signal and/or power to the cell transistor included in the cell array area MCA. In some embodiments of the present inventive concept, the peripheral circuit transistor may constitute various circuits, such as a command decoder, a control logic, an address buffer, a row decoder, a column decoder, a sense amplifier, and a data input-output circuit.

According to some embodiments of the present inventive concept, the substrate 110 may include a plurality of active areas AC. According to some embodiments of the present inventive concept, in the cell array area MCA, the plurality of active areas AC may be arranged to have a long axis in a third direction having a certain angle α with respect to a first direction (e.g., the Y direction). According to some embodiments of the present inventive concept, the plurality of active areas AC may be separated from each other in first, second and third directions.

According to some embodiments of the present inventive concept, a plurality of bit lines BL may extend in parallel to each other in the first direction (e.g., the Y direction). The plurality of bit lines BL may extend in the first direction (e.g., the Y direction) and be separated by a first interval t₁ from each other in a second direction (e.g., the X direction). According to some embodiments of the present inventive concept, a plurality of word lines WL may extend in parallel to each other in the second direction (e.g., the X direction). The plurality of word lines WL may extend in the second direction (e.g., the X direction) and be separated by a second interval t₂ from each other in the first direction (e.g., the Y direction).

According to some embodiments of the present inventive concept, the plurality of active areas AC may extend in the third direction having the certain angle α with respect to the first direction. The plurality of active areas AC may be inclined or slanted in the third direction having a certain slope with respect to the first direction (e.g., the Y direction). The certain slope may be a ratio of two first intervals t₁ to four second intervals t₂. For example, a first-direction vertical distance between a center 1 of a long axis of a first active area AC and a center 1′ of a long axis of a second active area AC adjacent to the first active area AC in the third direction may be about four times the second interval t₂. A second-direction vertical distance between the center 1 of the long axis of the first active area AC and the center 1′ of the long axis of the second active area AC may be about two times the first interval t₁.

For example, the first-direction vertical distance may be a Y-axis directional distance between the center 1 of the long axis of the first active area AC and the center 1′ of the long axis of the second active area AC. The second-direction vertical distance may be an X-axis directional distance between the center 1 of the long axis of the first active area AC and the center 1′ of the long axis of the second active area AC.

Herein, a ratio of a distance of the first interval t₁ to a distance of the second interval t₂ may be about 3:2.6. According to some embodiments of the present inventive concept, the certain angle α formed by the plurality of active areas AC and the first direction may be about 30°.

According to some embodiments of the present inventive concept, by arranging the plurality of active areas AC such that a long axis of an active area AC is parallel to the third direction, an area of the active area AC that is in contact with the capacitor structure may increase. Herein, the capacitor structure may have a honeycomb structure on an upper surface of the substrate 110.

According to some embodiments of the present inventive concept, two word lines WL may pass between active areas AC adjacent to each other in the third direction. For example, two word lines WL parallel to the second direction may be between a first active area AC and a second active area AC arranged on a line in the third direction. According to arrangements of the plurality of active areas AC and the plurality of word lines WL, an area of an active area AC that is in contact with the capacitor structure may increase.

According to some embodiments of the present inventive concept, the semiconductor device 100 according to some embodiment of the present inventive concept may include the plurality of active areas AC of which long axes have the certain angle α with respect to the first direction (e.g., the Y direction), thereby directly connecting an active area AC to the capacitor structure. For example, an active area AC may be directly connected to the capacitor structure without a horizontal structure, such as a landing pad, thereby reducing the number of process steps. In addition, the reduction of the number of process steps may cause a manufacturing cost and time of the semiconductor device 100 to be saved.

FIG. 3 illustrates cross-sectional views taken along lines A-A′ and B-B′ of FIG. 2.

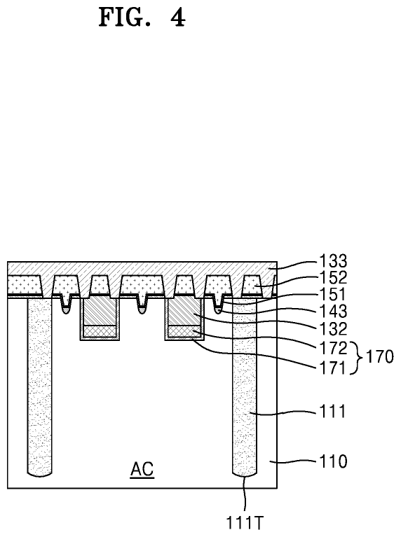

FIG. 4 is a cross-sectional view of a core area of the semiconductor device 100 in the first direction, according to an embodiment of the present inventive concept.

For example, FIG. 4 is a cross-sectional view of a portion of a first-direction cross-section of a peripheral circuit area PCA (see FIG. 1) including a peripheral circuit transistor and the like configured to provide a signal and/or power to a cell transistor included in a cell array area MCA (see FIG. 1).

Referring to FIGS. 3 and 4, the semiconductor device 100 according to an embodiment of the present inventive concept may include all or some of the substrate 110 including the plurality of active areas AC, the plurality of word lines WL, the plurality of bit lines BL, a contact structure, and a capacitor structure CP.

The semiconductor device 100 according to an embodiment of the present inventive concept may be formed in a state in which the plurality of bit lines BL and the plurality of word lines WL are disposed in the substrate 110. In some embodiments of the present inventive concept, the plurality of active areas AC, the plurality of bit lines BL, and the plurality of word lines WL may be arranged such that the semiconductor device 100 has a unit cell structure of 6F2. Herein, F denotes the minimum feature size.

The substrate 110 may include silicon (Si), e.g., monocrystalline silicon, polycrystalline silicon, or amorphous silicon. In some embodiments of the present inventive concept, the substrate 110 may include at least one of germanium (Ge), silicon germanium (SiGe), silicon carbide (SiC), gallium arsenide (GaAs), indium arsenide (InAs), and indium phosphide (InP). In some embodiments of the present inventive concept, the substrate 110 may include a conductive area, e.g., an impurity-doped well or an impurity-doped structure. An insulating layer including silicon oxide may be on the upper surface of the substrate 110. Hereinafter, the first direction (e.g., the Y direction) and the second direction (e.g., the X direction) are defined as directions parallel to the upper surface of the substrate 110 and substantially perpendicular to each other, and the vertical direction (e.g., the Z direction) is defined as a direction substantially perpendicular to the upper surface of the substrate 110.

The substrate 110 may include the plurality of active areas AC linearly extending in the third direction (see FIG. 2). In a top view, a long axis of an active area AC may be parallel to the third direction. The active area AC may have thereon source/drain areas formed by an ion implant process and separated from each other in the third direction.

According to some embodiments of the present inventive concept, a portion of the source/drain areas may be in contact with the contact structure, and the other portion of the source/drain areas may be in contact with a bit line BL.

According to some embodiments of the present inventive concept, the plurality of active areas AC may be inclined or slanted in the third direction having a certain slope with respect to the first direction (e.g., the Y direction). The certain slope may be a ratio of two first intervals t₁ to four second intervals t₂. According to some embodiments of the present inventive concept, the certain angle α formed by the plurality of active areas AC and the first direction may be about 30°.

A plurality of device isolation layers 111 defining the plurality of active areas AC may be disposed in the substrate 110. The plurality of device isolation layers 111 may include an insulating material filling a device isolation trench 111T formed in the substrate 110. Two device isolation layers 111 may be separated from each other with one active area AC disposed therebetween. One device isolation layer 111 may be disposed between two neighboring active areas AC. The plurality of device isolation layers 111 may include, for example, an oxide layer, a nitride layer, or a combination thereof.

The plurality of bit lines BL may be respectively provided inside a plurality of bit line trenches formed in the substrate 110. The plurality of bit line trenches may extend in the first direction (e.g., the Y direction) and be separated from each other in the second direction (e.g., the X direction). The plurality of bit lines BL may extend in the first direction (e.g., the Y direction) and be separated from each other in the second direction (e.g., the X direction). A bit line BL may fill a lower portion of a corresponding bit line trench. A bit line trench may pass through an active area AC and/or a device isolation layer 111 in the first direction (e.g., the Y direction).

In some embodiments of the present inventive concept, a bit line BL may be in direct contact with an active area AC. The plurality of bit lines BL may include a conductive material, e.g., Si, Ge, tungsten (W), tungsten nitride (WN), cobalt (Co), nickel (Ni), aluminum (Al), molybdenum (Mo), ruthenium (Ru), titanium (Ti), titanium nitride (TiN), tantalum (Ta), tantalum nitride (TaN), copper (Cu), or a combination thereof. Each of the plurality of bit lines BL may include a conductive layer having a single-layer structure or a multi-layer structure.

A plurality of second capping layers 132 may be on the plurality of bit lines BL, respectively. A second capping layer 132 may at least partially cover an upper surface of a bit line BL. The second capping layer 132 may extend in the vertical direction (e.g., the Z direction) from an upper surface of a corresponding bit line BL toward the upper surface of the substrate 110. The second capping layer 132 may include, for example, silicon nitride.

A first connection layer 141 may be at one end of each of the plurality of bit lines BL. The first connection layer 141 may be at a portion where a bit line BL is in contact with an active area AC. For example, the first connection layer 141 may be between the corresponding bit line BL and the active area AC. The first connection layer 141 may include, for example, cobalt silicide. The first connection layer 141 may decrease a resistance between the bit line BL and the active area AC so that the bit line BL is in contact with the active area AC. For example, the bit line BL may be connected to the active area AC. For example, when the bit line BL is not a metal, the first connection layer 141 may be omitted.

The capacitor structure CP may be connected to an active area AC via the contact structure. An individual capacitor structure CP may be electrically connected to a corresponding individual active area AC via a corresponding individual contact structure.

The contact structure may include all or some of a metal layer 150, an adhesive layer 151, and a second connection layer 142. The metal layer 150 may include a conductive material, e.g., Si, Ge, W, WN, Co, Ni, Al, Mo, Ru, Ti, TiN, Ta, TaN, Cu, or a combination thereof. The adhesive layer 151 may be beneath the metal layer 150. The adhesive layer 151 may cover the upper surface of the substrate 110 while covering a portion of the metal layer 150. The adhesive layer 151 may include any one of, for example, metal nitride, a metal, and a mixed material thereof. The adhesive layer 151 may include, for example, TiN. The second connection layer 142 may be disposed beneath the adhesive layer 151. The second connection layer 142 may be at a portion where the contact structure is in contact with an active area AC. For example, the second connection layer 142 may be disposed between the adhesive layer 151 and the active area AC. The second connection layer 142 may include, for example, cobalt silicide.

A third capping layer 133 may be disposed on the contact structure. The third capping layer 133 may at least partially cover an upper surface of the contact structure. The third capping layer 133 may extend in the vertical direction (e.g., the Z direction) from the upper surface of the contact structure toward the upper surface of the substrate 110. The third capping layer 133 may include, for example, silicon boron nitride (SiBN).

The plurality of word lines WL may be respectively provided inside a plurality of word line trenches formed in the substrate 110. The plurality of word line trenches may extend in the second direction (e.g., the X direction) and may be separated from each other in the first direction (e.g., the Y direction). The plurality of word lines WL may extend in a direction intersecting with the plurality of bit lines BL. For example, the plurality of word lines WL may be substantially perpendicular to the plurality of bit lines BL. The plurality of word lines WL may extend in the second direction (e.g., the X direction) and may be separated by the second interval t₂ from each other in the first direction (e.g., the Y direction). An individual word line WL may fill a lower portion of a corresponding word line trench. The plurality of word lines WL may include a conductive material, e.g., Si, Ge, W, WN, Co, Ni, Al, Mo, Ru, Ti, TiN, Ta, TaN, Cu, or a combination thereof.

A plurality of first capping layers 131 may be disposed on the plurality of word lines WL, respectively. A first capping layer 131 may cover an upper surface of a corresponding individual word line WL inside a corresponding individual word line trench. The first capping layer 131 may extend in the vertical direction (e.g., the Z direction) from an upper surface of a corresponding individual word line WL toward the upper surface of the substrate 110. The first capping layer 131 may include, for example, silicon nitride.

In some embodiments of the present inventive concept, an upper surface of a bit line BL and an upper surface of a word line WL may be at substantially the same vertical level as or at a vertical level lower than that of the upper surface of the substrate 110. The bit line BL and the word line WL may be disposed under the upper surface of the substrate 110. In addition, in some embodiments of the present inventive concept, the word line WL may be disposed at a vertical level lower than that of the bit line BL. For example, the upper surface of the word line WL may be disposed at a vertical level lower than that of an upper surface of the bit line BL.

A word line trench may be formed to be deeper than a bit line trench. For example, a distance between the upper surface of the substrate 110 and a lower end of the bit line trench in the vertical direction (e.g., the Z direction) may be less than a distance between the upper surface of the substrate 110 and a lower end of the word line trench in the vertical direction (e.g., the Z direction). In addition, the word line WL may be at a lower vertical level than that of the bit line BL. For example, a distance between the upper surface of the substrate 110 and an upper surface of the bit line BL in the vertical direction (e.g., the Z direction) may be less than a distance between the upper surface of the substrate 110 and an upper surface of the word line WL in the vertical direction (e.g., the Z direction).

The semiconductor device 100 may include the capacitor structure CP above the substrate 110. The capacitor structure CP may include a plurality of lower electrodes 162, an upper electrode 166 disposed above the plurality of lower electrodes 162, and a dielectric layer 164 disposed between the upper electrode 166 and the plurality of lower electrodes 162.

Although FIG. 3 shows that the plurality of lower electrodes 162 have a cylindrical structure, the plurality of lower electrodes 162 are not limited thereto and may have a pillar structure. The dielectric layer 164 may conformally extend along the surfaces of the plurality of lower electrodes 162. The plurality of lower electrodes 162 may be electrically isolated from the upper electrode 166 so that the plurality of lower electrodes 162 and the upper electrode 166 function as a capacitor. The dielectric layer 164 may include at least one of, for example, silicon oxide, silicon nitride, silicon oxynitride, and a high-k material. The upper electrode 166 may be formed to cover the plurality of lower electrodes 162. The upper electrode 166 may include any one of, for example, metal nitride, a metal, and a mixed material thereof. For example, the upper electrode 166 may include at least one of TiN, Ru, TaN, Wn, platinum (Pt), and iridium (Ir).

It may be defined that lower electrodes 162 arranged in parallel in the first direction (e.g., the Y direction) among the plurality of lower electrodes 162 constitute one column. The lower electrodes 162 constituting one column may constantly have a first pitch interval (i.e., a distance between the centers of two lower electrodes 162 neighboring in the first direction (e.g., the Y direction)). To arrange as many number of lower electrodes 162 as possible in a limited area, lower electrodes 162 constituting any one column may shift by a certain distance (e.g., a distance corresponding to a half of the first pitch interval) in the first direction (e.g., the Y direction) from lower electrodes 162 constituting another neighboring column. Accordingly, in a top view, the plurality of lower electrodes 162 may be arranged in a zigzag shape or a staggered shape. For example, the lower electrodes 162 may have an alternating arrangement.

The plurality of lower electrodes 162 may be arranged in a honeycomb structure above the upper surface of the substrate 110. In a top view, the honeycomb structure of the plurality of lower electrodes 162 may be defined by six lower electrodes 162 positioned at the six vertices of a hexagon and one lower electrode 162 positioned at the center of the hexagon. The plurality of lower electrodes 162 may have a structure in which honeycomb structures continue by partially overlapping each other in the first direction (e.g., the Y direction) and the second direction (e.g., the X direction). For example, lower electrodes 162 positioned at the six vertices and the center point of a hexagon may form one honeycomb structure, and the six vertices of the hexagon may be the center points of other hexagons forming other honeycomb structures, respectively. In some embodiments of the present inventive concept, the hexagon of the honeycomb structure may be a regular hexagon. However, the honeycomb structure is not limited thereto and may be designed as a hexagon but not a regular hexagon.

The semiconductor device 100 may include a support 181 supporting the plurality of lower electrodes 162 by connecting the plurality of lower electrodes 162 to each other. For example, the support 181 may support a sidewall of an upper portion of each of the plurality of lower electrodes 162. For example, the support 181 may support a sidewall of a middle portion of each of the plurality of lower electrodes 162. The support 181 may support the plurality of lower electrodes 162 to prevent falling and bending of the plurality of lower electrodes 162. For example, the support 181 may include an insulating layer, e.g., silicon oxide, silicon nitride, silicon oxynitride, or a combination thereof.

Referring to FIG. 4, the core area of the semiconductor device 100 according to an embodiment of the present inventive concept may include all or some of the substrate 110 including the plurality of active areas AC, the plurality of device isolation layers 111, and a gate structure 170.

The gate structure 170 may include a gate electrode 172 and a gate insulating layer 171. A gate structure trench may be formed in the substrate 110, and the gate insulating layer 171, the gate electrode 172, and the second capping layer 132 may be sequentially formed inside the gate structure trench.

The gate insulating layer 171 may include, for example, a silicon oxide layer, a silicon nitride layer, a silicon oxynitride layer, an oxide/nitride/oxide (ONO) layer, or a high-k dielectric layer having a dielectric constant higher than the silicon oxide layer. The gate electrode 172 may include, for example, Ti, TiN, Ta, TaN, W, WN, titanium silicon nitride (TiSiN), tungsten silicon nitride (WSiN), or a combination thereof. The second capping layer 132 may include silicon nitride.

The gate electrode 172 may extend in the first direction (e.g., the Y direction) and be electrically connected to the metal layer 150 of the contact structure, a word line WL, and the like. The gate electrode 172 may be connected to the contact structure to electrically connect a memory cell area to the core area.

In some embodiments of the present inventive concept, the gate structure 170 may have substantially the same vertical level as or a vertical level lower than that of the upper surface of the substrate 110. The gate structure 170 may be disposed under the upper surface of the substrate 110. In addition, in some embodiments of the present inventive concept, the gate electrode 172 may be disposed under the upper surface of the substrate 110.

The adhesive layer 151, a wiring layer 152, and the third capping layer 133 may be disposed on the second capping layer 132 and the upper surface of the substrate 110. A third connection layer 143 may be at a portion where the wiring layer 152 is in contact with the active area AC. For example, the third connection layer 143 may be disposed between the wiring layer 152 and the active area AC. For example, the second capping layer 132 may include silicon nitride, and the third capping layer 133 may include SiBN. The third capping layer 133 may at least partially cover the wiring layer 152. The third capping layer 133 may extend in the vertical direction (e.g., the Z direction) from an upper surface of the wiring layer 152 toward the upper surface of the substrate 110.

The wiring layer 152 may extend in the first direction (e.g., the Y direction) and be electrically connected to a word line WL and/or a bit line BL of the contact structure. The wiring layer 152 may be electrically connected to the word line WL and/or the bit line BL to electrically connect the memory cell area to the core area. In this case, the third capping layer 133 may be formed on the wiring layer 152 to prevent electrical connections between adjacent wiring layers 152. Herein, the wiring layer 152 may include a conductive material, e.g., Si, Ge, W, WN, Co, Ni, Al, Mo, Ru, Ti, TiN, Ta, TaN, Cu, or a combination thereof.

The adhesive layer 151 may allow the wiring layer 152 to adhere to the second capping layer 132 and/or the upper surface of the substrate 110. Herein, the adhesive layer 151 may include any one of, for example, metal nitride, a metal, and a mixed material thereof. The adhesive layer 151 may include, for example, TiN.

The third connection layer 143 may be formed at portions where a plurality of wiring layers 152 are in contact with the active area AC. For example, the third connection layer 143 may be formed only at portions where a plurality of wiring layers 152 are in contact with the active area AC. The third connection layer 143 may include, for example, cobalt silicide. The third connection layer 143 may be formed by a salicide method in an area in which the wiring layer 152 is in contact with the active area AC. According to some embodiments of the present inventive concept, by forming the gate structure 170 under the upper surface of the substrate 110 in the core area, a short channel effect may be improved.

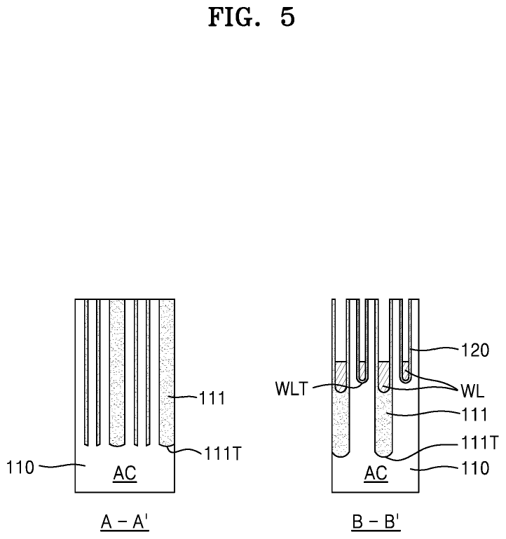

FIGS. 5 to 12 illustrate a method of manufacturing a semiconductor device with cross-sectional views taken along lines A-A′ and B-B′, according to an embodiment of the present inventive concept.

Referring to FIG. 5, the substrate 110 having the active area AC is prepared. The plurality of device isolation layers 111 defining the plurality of active areas AC may be formed in the substrate 110. Each of the plurality of active areas AC may have source/drain areas formed by an ion implant process.

A plurality of word line spacers 120 may be inside a plurality of word line trenches WLT, respectively. A word line spacer 120 may extend along the surface of the substrate 110 defining a corresponding word line trench WLT. The word line spacer 120 may extend along the bottom surface and a side wall of the word line WL and be between the word line WL and the substrate 110. The word line spacer 120 may include an insulating material, e.g., silicon oxide, silicon nitride, silicon oxynitride, an ONO layer, or a high-k dielectric layer having a dielectric constant higher than that of the silicon oxide. The word line spacer 120 may be referred to as a gate insulating layer.

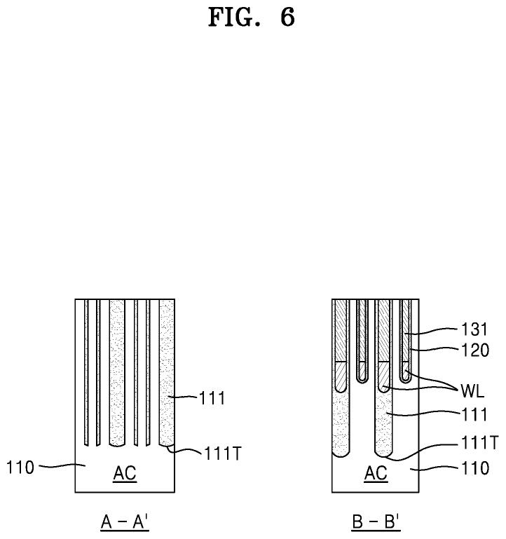

Referring to FIG. 6, the plurality of first capping layers 131 may be formed on the plurality of word lines WL, respectively. The first capping layer 131 may be formed by being deposited on the word line WL and then polished (e.g., chemical mechanical polishing (CMP)). The first capping layer 131 may be referred to as a word line capping insulating layer. The first capping layer 131 may cover an upper surface of a corresponding individual word line WL inside a corresponding individual word line trench WLT. The first capping layer 131 may extend in the vertical direction (e.g., the Z direction) from an upper surface of a corresponding individual word line WL toward the upper surface of the substrate 110. The first capping layer 131 may include, for example, silicon nitride.

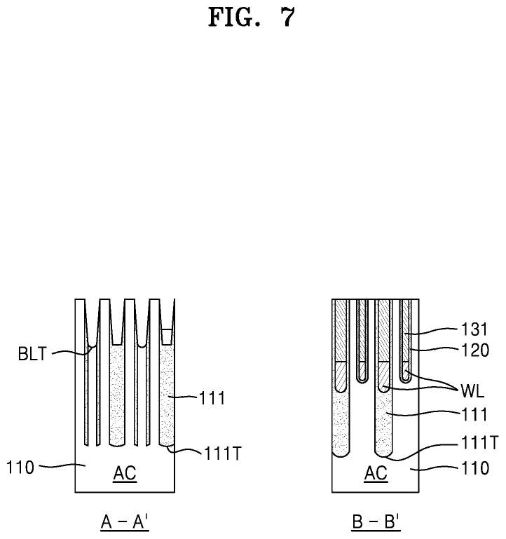

Referring to FIG. 7, a bit line trench BLT may be formed. The bit line trench BLT may be formed by forming a mask pattern on at least portions of the active area AC and a device isolation layer 111 and etching portions that are exposed by the mask pattern. The bit line trench BLT may be formed by extending downward from the upper surface of the substrate 110.

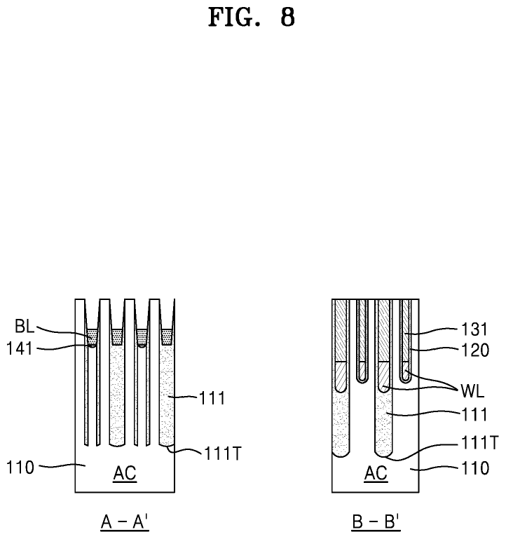

Referring to FIG. 8, the first connection layer 141 and the plurality of bit lines BL may be formed. The first connection layer 141 may be formed at portions where a plurality of bit line trenches BLT (see FIG. 7) are in contact with the active area AC. For example, the first connection layer 141 may be disposed between the plurality of bit lines BL and the active area AC. The first connection layer 141 may include, for example, cobalt silicide. The first connection layer 141 may be formed by a salicide method in an area in which the bit line BL is in contact with the active area AC.

Each of the plurality of bit lines BL may be formed inside the bit line trench BLT (see FIG. 7). The bit line BL may be deposited inside the bit line trench BLT (see FIG. 7), and then, the bit line BL filling the bit line trench BLT (see FIG. 7) may be etched back. Herein, the bit line BL may include, for example, Si, Ge, W, WN, Co, Ni, Al, Mo, Ru, Ti, TiN, Ta, TaN, Cu, or a combination thereof.

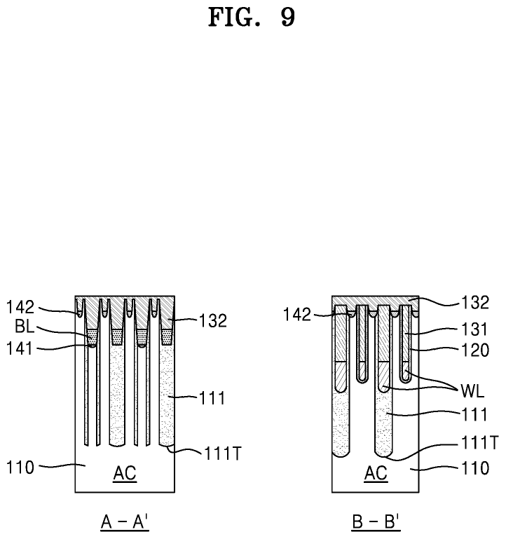

Referring to FIG. 9, the plurality of second capping layers 132 may be formed on the plurality of bit lines BL, respectively. The second capping layer 132 may be formed by being deposited on the bit line BL and then polished (CMP). The second capping layer 132 may be referred to as a bit line capping insulating layer. The second capping layer 132 may cover an upper surface of a corresponding individual bit line BL inside a corresponding individual bit line trench. In addition, the second capping layer 132 may cover the first capping layer 131, the word line spacer 120, and the active area AC. The second capping layer 132 may include, for example, silicon nitride.

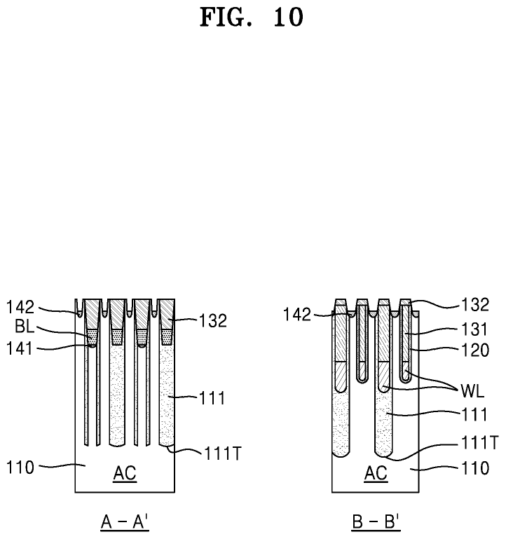

Referring to FIG. 10, a contact structure trench may be formed. The contact structure trench may be formed by forming a mask pattern on at least a portion of the second capping layer 132 and etching a portion that is exposed by the mask pattern. The contact structure trench may be formed by extending downward from the upper surface of the substrate 110.

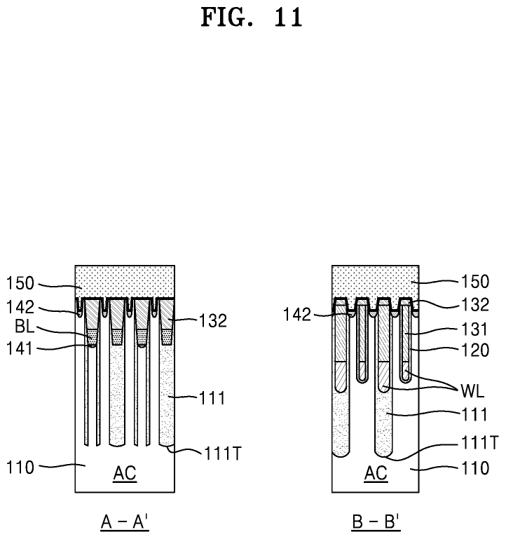

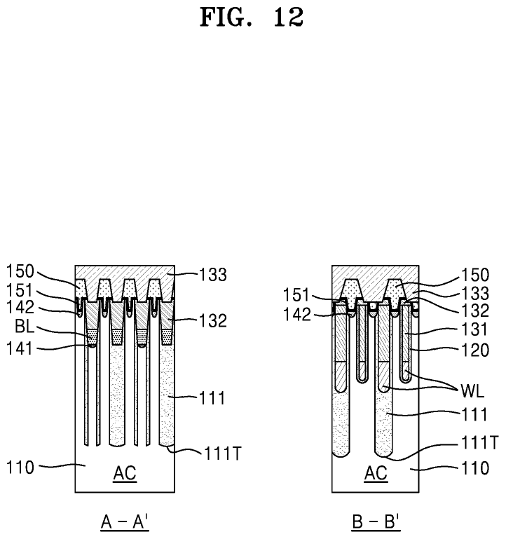

Referring to FIG. 11, the metal layer 150, the adhesive layer 151 (see FIG. 12), and the second connection layer 142 may be formed. The second connection layer 142 may be formed at a portion where the contact structure is in contact with the active area AC. The second connection layer 142 may include, for example, cobalt silicide. The second connection layer 142 may be formed by a salicide method in an area in which the contact structure is in contact with the active area AC.

The metal layer 150 and the adhesive layer 151 (see FIG. 12) may be formed inside a contact structure trench. The adhesive layer 151 (see FIG. 12) may be deposited inside the contact structure trench, and then, the metal layer 150 may be deposited on an upper surface of the adhesive layer 151 (see FIG. 12). Herein, the metal layer 150 may include a conductive material, e.g., Si, Ge, W, WN, Co, Ni, Al, Mo, Ru, Ti, TiN, Ta, TaN, Cu, or a combination thereof. The adhesive layer 151 (see FIG. 12) may include any one of, for example, metal nitride, a metal, and a mixed material thereof. The adhesive layer 151 (see FIG. 12) may include, for example, TiN.

Referring to FIG. 12, the contact structure may be cut. At least portions of the metal layer 150 and the adhesive layer 151 may be cut. After the contact structure is cut, the third capping layer 133 may be formed. The third capping layer 133 may be on the contact structure. The third capping layer 133 may partially cover the upper surface of the contact structure. The third capping layer 133 may extend in the vertical direction (e.g., the Z direction) from the upper surface of the contact structure toward the upper surface of the substrate 110. The third capping layer 133 may include, for example, SiBN.

Next, referring to FIG. 3, the capacitor structure CP may be formed. The plurality of lower electrodes 162, the upper electrode 166 disposed above the plurality of lower electrodes 162, and the dielectric layer 164 disposed between the upper electrode 166 and the plurality of lower electrodes 162 may be formed. The dielectric layer 164 conformally covering the lower electrode 162 and the support 181 may be formed, and the upper electrode 166 covering the whole surface of the dielectric layer 164 may be formed. The dielectric layer 164 may be conformally formed along the surface of the lower electrode 162 and the surface of the support 181. The dielectric layer 164 may include at least one of, for example, silicon oxide, silicon nitride, silicon oxynitride, and a high-k material.

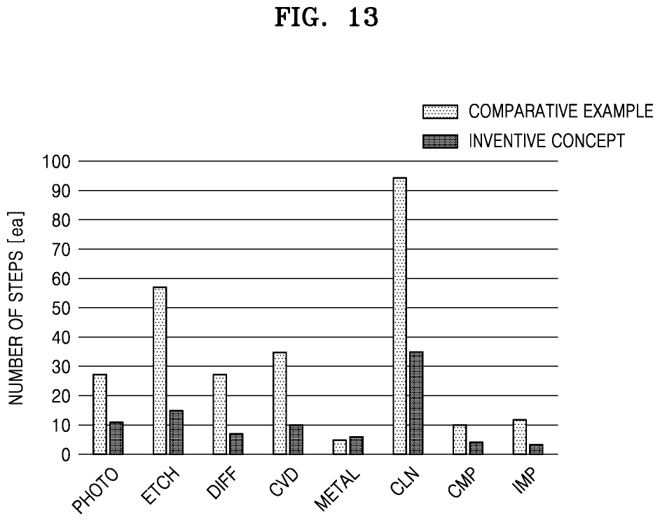

FIG. 13 is a graph illustrating the number of steps for each process in a method of manufacturing a semiconductor device, according to an embodiment of the present inventive concept.

Referring to FIG. 13, compared to a method of manufacturing a semiconductor device, according to a comparative example, in a method of manufacturing the semiconductor device 100, according to an embodiment of the present inventive concept, the number of steps for each process is reduced. For example, in a method of manufacturing a semiconductor device, except for a process of manufacturing a buried cell array transistor (BCAT) and a process of manufacturing a capacitor structure CP, the number of steps for each of processes of forming a bit line BL, a contact structure, and the like may be reduced.

While the number of steps of a photo process is 27 in the comparative example, the number of steps of the photo process may be reduced to 11 in the method of manufacturing the semiconductor device 100, according to an embodiment of the present inventive concept. Compared to the comparative example, the number of process steps may be reduced to about 41%.

While the number of steps of an etching process is 57 in the comparative example, the number of steps of the etching process may be reduced to 15 in the method of manufacturing the semiconductor device 100, according to an embodiment of the present inventive concept. Compared to the comparative example, the number of process steps may be reduced to about 26%.

While the number of steps of a diffusion process is 27 in the comparative example, the number of steps of the diffusion process may be reduced to 7 in the method of manufacturing the semiconductor device 100, according to an embodiment of the present inventive concept. Compared to the comparative example, the number of process steps may be reduced to about 26%.

While the number of steps of a chemical vapor deposition (CVD) process is 35 in the comparative example, the number of steps of the CVD process may be reduced to 10 in the method of manufacturing the semiconductor device 100, according to an embodiment of the present inventive concept. Compared to the comparative example, the number of process steps may be reduced to about 29%.

While the number of steps of a metal process is 5 in the comparative example, the number of steps of the etching process may increase to 6 in the method of manufacturing the semiconductor device 100, according to an embodiment of the present inventive concept. Compared to the comparative example, the number of process steps may increase to about 120%.

While the number of steps of a clean process is 94 in the comparative example, the number of steps of the clean process may be reduced to 35 in the method of manufacturing the semiconductor device 100, according to an embodiment of the present inventive concept. Compared to the comparative example, the number of process steps may be reduced to about 37%.

While the number of steps of a CMP process is 10 in the comparative example, the number of steps of the CMP process may be reduced to 4 in the method of manufacturing the semiconductor device 100, according to an embodiment of the present inventive concept. Compared to the comparative example, the number of process steps may be reduced to 40%.

While the number of steps of an ion implant process is 12 in the comparative example, the number of steps of the ion implant process may be reduced to 3 in the method of manufacturing the semiconductor device 100, according to an embodiment of the present inventive concept. Compared to the comparative example, the number of process steps may be reduced to about 25%.

According to an embodiment of the present inventive concept, the total number of process steps of the semiconductor device 100 may be 91. Compared to 267 that is the total number of process steps of the comparative example, the total number of process steps in the method of manufacturing the semiconductor device 100 may be reduced to about 34%.

According to an embodiment of the present inventive concept, because the active area AC has a certain slope, the active area AC may be in direct contact with the capacitor structure CP via the contact structure in the vertical direction. Therefore, a vertical contact area between the capacitor structure CP and the active area AC may increase.

In addition, as described above, horizontal intermediate structures, such as a landing pad, may be omitted, and the active area AC may be connected to the capacitor structure CP, thereby reducing the number of process steps for the semiconductor device 100. In addition, the manufacturing cost and time of the semiconductor device 100 may be reduced.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor device comprising:
an active area formed on a substrate;
bit lines extending in a first direction and formed inside the substrate by passing through the active area, wherein the bit lines are formed at first intervals in a second direction that is substantially perpendicular to the first direction;
word lines formed inside the substrate by passing through the active area, and extending below the bit lines in the second direction, wherein the word lines are formed at second intervals in the first direction;
a contact structure formed on the active area and adjacent to the bit lines, wherein the contact structure comprises a metal layer and an adhesive layer; and
a capacitor structure formed on the contact structure,
wherein the active area is inclined in a third direction having a certain slope with respect to the first direction, and the certain slope is a ratio of two first intervals to four second intervals.

2. The semiconductor device of claim 1, wherein the third direction is inclined by about 30° with respect to the first direction.

3. The semiconductor device of claim 1, wherein the capacitor structure is arranged in a honeycomb structure.

4. The semiconductor device of claim 1, further comprising a first connection layer disposed between a bit line of the bit lines and the active area.

5. The semiconductor device of claim 1, wherein the capacitor structure is connected to the active area via the contact structure.

6. The semiconductor device of claim 1, wherein the contact structure further comprises a second connection layer in contact with the active area.

7. The semiconductor device of claim 1, wherein the bit lines are disposed below an upper surface of the substrate.

8. The semiconductor device of claim 1, further comprising a gate structure connected to the contact structure in the first direction,
wherein the gate structure is disposed below an upper surface of the substrate.

9. The semiconductor device of claim 8, wherein the gate structure further comprises:
a gate electrode connected to the contact structure; and
a gate insulating layer disposed between the gate electrode and the active area.

10. The semiconductor device of claim 1, wherein the active area comprises source/drain areas, wherein a portion of the source/drain areas is in contact with the contact structure, and another portion of the source/drain areas is in contact with a bit line.

11. A method of manufacturing a semiconductor device, the method comprising:
defining an active area by forming a device isolation layer on a substrate;
forming a word line extending in a second direction across the active area and the device isolation layer;
forming a first capping layer covering the word line;
forming a bit line extending in a first direction across the first capping layer, the active area, and the device isolation layer, wherein the first direction is substantially perpendicular to the second direction;
forming a second capping layer covering the bit line;
forming a contact structure including a metal layer and an adhesive layer on the second capping layer;
forming a third capping layer on the contact structure; and
forming a capacitor structure on the third capping layer,
wherein the defining of the active area comprises defining that the active area is inclined in a third direction having a certain slope with respect to the first direction, wherein the third direction is inclined by about 300 with respect to the first direction.

12. The method of claim 11, wherein the forming of the bit line further comprises forming a first connection layer between the bit line and the active area.

13. The method of claim 12, wherein the first connection layer is formed by a salicide method.

14. The method of claim 11, wherein the forming of the bit line comprises:
forming, in the substrate, a bit line trench extending in the first direction; and
depositing the bit line inside the bit line trench and etching back the bit line.

15. The method of claim 11, wherein the forming of the contact structure further comprises forming a second connection layer between the metal layer and the active area.

16. The method of claim 11, further comprising forming a gate structure connected to the contact structure in the first direction,
wherein the gate structure is disposed in the substrate.

17. A semiconductor device comprising:
an active area formed on a substrate;
bit lines extending in a first direction and formed inside the substrate by passing through the active area, and wherein the bit lines are formed at first intervals in a second direction that is substantially perpendicular to the first direction;
word lines formed inside the substrate by passing through the active area, and extending below the bit lines in the second direction, wherein the word lines are formed at second intervals in the first direction;
a first capping layer disposed on the word lines;
a second capping layer disposed on the bit lines;
a contact structure formed on the active area and adjacent to the bit lines, wherein the contact structure comprises a metal layer and an adhesive layer;
a third capping layer disposed on the contact structure; and
a capacitor structure formed in a honeycomb structure on the contact structure,
wherein the active area is inclined by about 30° with respect to the first direction by being arranged at a ratio of two first intervals to four second intervals.

18. The semiconductor device of claim 17, further comprising a first connection layer disposed between a bit line of the bit lines and the active area.

19. The semiconductor device of claim 17, wherein the capacitor structure is connected to the active area via the contact structure.

20. The semiconductor device of claim 17, wherein the contact structure further comprises a second connection layer in contact with the active area.
